(19) United States
(12) Patent Application Publication
(10) Pub. No.: US 2006/0164135 A1
(43) Pub. Date: Jul. 27, 2006

(54) Driver circuit

(75) Inventors: Takao Myono, Saitama (JP); Yoshitaka Onaya, Gunma (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/337,809

(22) Filed: Jan. 24, 2006

(30) Foreign Application Priority Data
Jan. 24, 2005 (JP) 2005-015282

(51) Int. Cl. H03B 1/00

(52) U.S. Cl. 327/112

(57) ABSTRACT

An abnormal reduction in a positive high power supply electric potential VH outputted by a positive booster charge pump circuit at switching of an output stage inverter in a driver circuit is prevented. An output of an inverter INV2 is applied to an input terminal of an inverter INV4 for controlling an output transistor, and an output of the inverter INV4 is applied to a gate of an N-channel type MOS transistor of the output stage inverter INV6. The inverter INV4 is made of a P-channel type MOS transistor, a first resistor and an N-channel type MOS transistor connected between a positive high power supply electric potential VH and a negative high power supply electric potential VL, making a connecting node between the first resistor and the N-channel type MOS transistor an output terminal of the inverter INV4.

### CROSS-REFERENCE OF THE INVENTION

This invention is based on Japanese Patent Application No. 2005-015282, the content of which is incorporated herein by reference in its entirety.

### BACKGROUND OF THE INVENTION

1. Field of the Invention

This invention relates to a driver circuit, specifically to a driver circuit used for controlling a CCD (Charge Coupled Device) camera, for example.

2. Description of the Related Art

The driver circuit for controlling the CCD camera, which uses the CCD as an image pickup device and is incorporated into portable equipment such as a mobile phone, is required to meet specifications that allow a high voltage output. FIG. 3 is a circuit diagram showing such a driver circuit.

An input stage inverter INV1 is composed of a P-channel type MOS transistor 10 and an N-channel type MOS transistor 11 connected in series between a low power supply electric potential Vdd (+3V, for example) and a ground electric potential (0V). A positive booster charge pump circuit 12 generates a positive high power supply electric potential VH (+15V, for example) based on the low power supply electric potential Vdd, while a negative booster charge pump circuit 13 generates a negative high power supply electric potential VL (−7.5V, for example).

A CCD control voltage VIN is inputted to an input terminal of the inverter INV1. Output voltages of the inverter INV1 are level-shifted through a level shift circuit 14 in a next stage so that its high level becomes VH and its low level becomes VL.

An output of the level shift circuit 14 is applied to an input terminal of an inverter INV2 that is made of a P-channel type MOS transistor 15 and an N-channel type MOS transistor 16. An output of the inverter INV2 is applied to an input terminal of an output stage inverter INV3 that is made of a P-channel type MOS transistor 17 and an N-channel type MOS transistor 18.

The inverters INV2 and INV3 are provided with the positive high power supply electric potential VH as a higher electric potential side power supply and the negative high power supply electric potential VL as a lower electric potential side power supply. An output capacitor C that is externally attached to an IC (Integrated Circuit) is connected between an output terminal 19 of the output stage inverter INV3 and the negative high power supply electric potential VL through external wirings 20 and 21 which are outside the IC. Each of the external wirings 20 and 21 has each of parasitic inductances L1 and L2, respectively. The positive booster charge pump circuit 12 and the negative booster charge pump circuit 13 are described in Japanese Patent Application Publication No. 2001-231249.

With the driver circuit described above, however, it is observed that the positive high power supply electric potential VH, which is an output of the positive booster charge pump circuit 12, is abnormally reduced after the output voltage Vout of the output stage inverter INV3 changes from a high level to a low level, as shown in FIG. 4. It has appeared that this abnormal phenomenon does not occur when capacitance of the output capacitor C is 500 pF, but occurs when the capacitance is as large as 1000 pF that is required by specifications for controlling the CCD camera.

When such an abnormal phenomenon occurs, there arises a problem that other circuits in the IC, which use the positive power supply electric potential VH as the power supply electric potential, become unstable or malfunction.

Thus, the inventors have investigated the cause of the abnormal phenomenon and eventually developed a driver circuit of this invention. At first, the investigation of the cause will be explained. FIG. 5 is a cross-sectional view showing structures of the P-channel type MOS transistor 17 and the N-channel type MOS transistor 18 forming the output stage inverter INV3 in the driver circuit.

The P-channel type MOS transistor 17 is formed in a first N-well 51 formed in a surface of a P-type semiconductor substrate 50. The N-channel type MOS transistor 18 is formed in a P-well 53 formed in a second N-well 52 formed adjacent the first N-well 51 in the surface of the P-type semiconductor substrate 50. An electric potential of each of the first and second N-wells 51 and 52 is set at the positive high power supply electric potential VH (+15V) through each of first and second N-type layers 54 and 55, respectively, while an electric potential of the P-well 53 is set at the negative high power supply electric potential VL (−7.5V) through a P-type layer 56.

FIGS. 6A and 6B show results of simulations performed on the driver circuit shown in FIGS. 3 and 5 when the output voltage Vout changes from the high level to the low level. In FIGS. 6A and 6B, a vertical axis represents Vout while a horizontal axis represents time. FIG. 6B is a magnified view of a portion of FIG. 6A. The results of the simulations clearly show that ringing in the output voltage Vout is larger when the output capacitor C is 1000 pF than when it is 500 pF.

More specifically, a period of overshoot during which the output voltage Vout is lower than the negative high power supply electric potential VL (−7.5V) is as long as about 60 ns when the output capacitance is 1000 pF, while a period of overshoot during which the output voltage Vout is lower than the negative high power supply electric potential VL (−7.5V) is about 40 ns when the output capacitance C is 500 pF. A combined inductance of the parasitic inductances L1 and L2 is assumed to be 200 nH in the simulations.

The periods of overshoot are considered to correspond periods during which a parasitic diode composed of the P-well 53 and an N-type drain layer 57 of the N-channel type MOS transistor 18 as shown in FIG. 5 is turned on. That is, because the overshoot is large when the capacitance of the output capacitance C is 1000 pF, a large current flows through the parasitic diode, providing a parasitic bipolar transistor with a base current I_{B} to turn it on.

The parasitic bipolar transistor is composed of an emitter made of the N-type drain layer 57, a base made of the P-well 53,and a collector made of the second N-well 52, as shown in FIG. 5. A collector current I_{C} flows from the positive high power supply electric potential VH (+15V) through the second N-well 52 when the parasitic bipolar transistor is turned on. The flowing of the collector current I_{C} is considered to be responsible for the abnormal reduction in the positive high power supply electric potential VH (+15V) that is outputted by the positive booster charge pump circuit 12.

Therefore, the cause of the abnormal reduction in the positive high power supply electric potential VH (+15V) is the overshoot of the output voltage Vout of the output stage inverter INV3 toward negative voltage beyond the negative high power supply electric potential VL (−7.5V) caused by an LC circuit formed of the output capacitor C and the parasitic inductances L1 and L2 derived from the external wirings 20 and 21. In order reduce the overshoot, it is conceivable to insert an output resistor between the output terminal 19 and the output capacitor C. However, it increases an output impedance of the output stage inverter INV3 and does not satisfy the specifications required for the circuit.

### SUMMARY OF THE INVENTION

A driver circuit of this invention includes a first resistor R1 for limiting an overshoot disposed in an inverter INV4 in a stage preceding an output stage inverter INV6, as shown in FIG. 1. As a result, the overshoot of an output voltage Vout of the output stage inverter INV6 toward negative voltage beyond the negative high power supply electric potential VL (−7.5V) is limited and turning on of the parasitic bipolar transistor as described above is prevented without increasing an output impedance of the output stage inverter INV6.

### BRIEF DESCRIPTION OF THE DRAWINGS

FIG. 1 is a circuit diagram of a driver circuit according to an embodiment of this invention.

FIG. 2 shows a result of a simulation of the driver circuit according to the embodiment of this invention.

FIG. 3 is a circuit diagram of a driver circuit according to a prior art.

FIG. 4 is an operational waveform diagram of the driver circuit according to the prior art.

FIG. 5 is a cross-sectional view showing a structure of an output stage inverter INV3 in the driver circuit.

FIGS. 6A and 6B show results of simulations of the driver circuit according to the prior art.

### DETAILED DESCRIPTION OF THE INVENTION

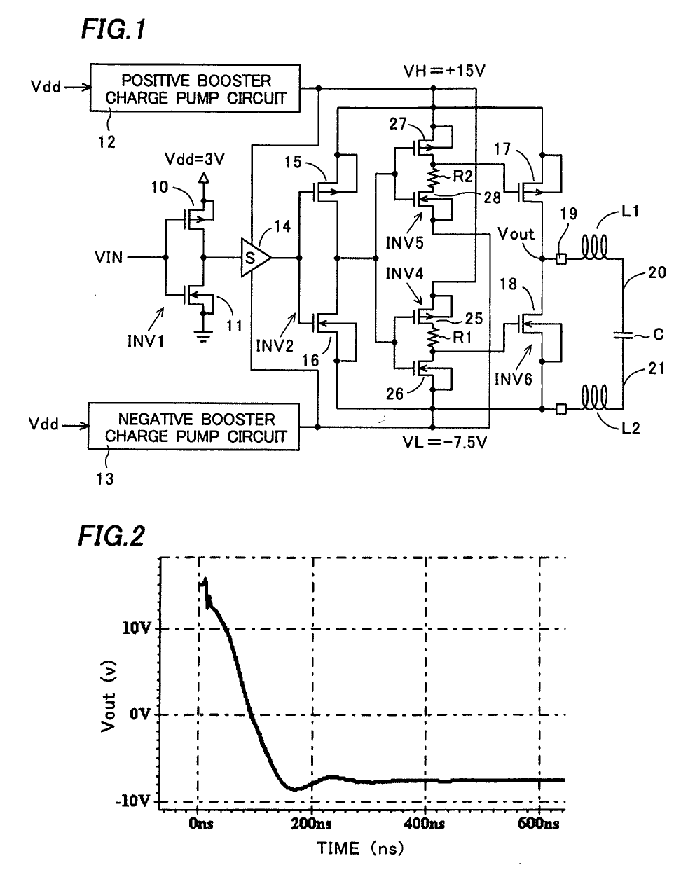

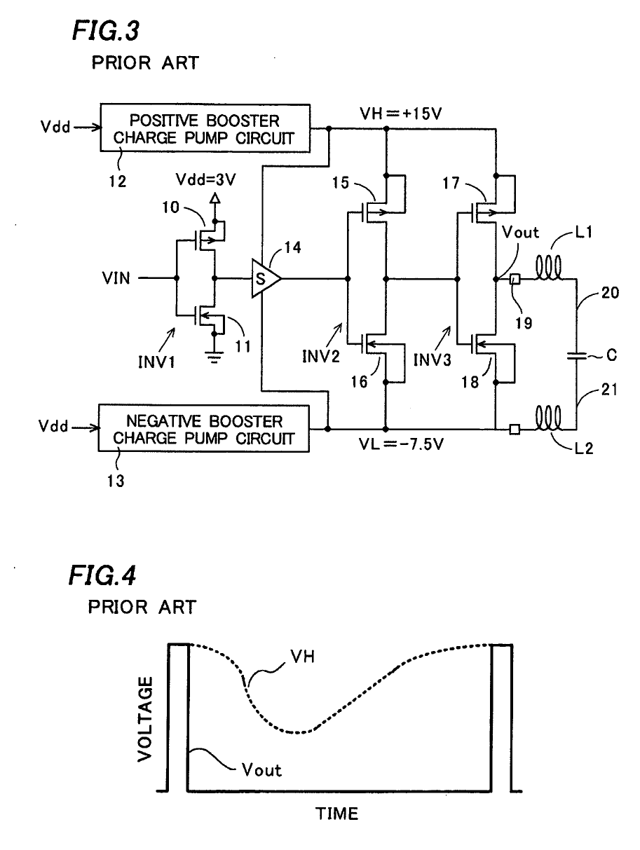

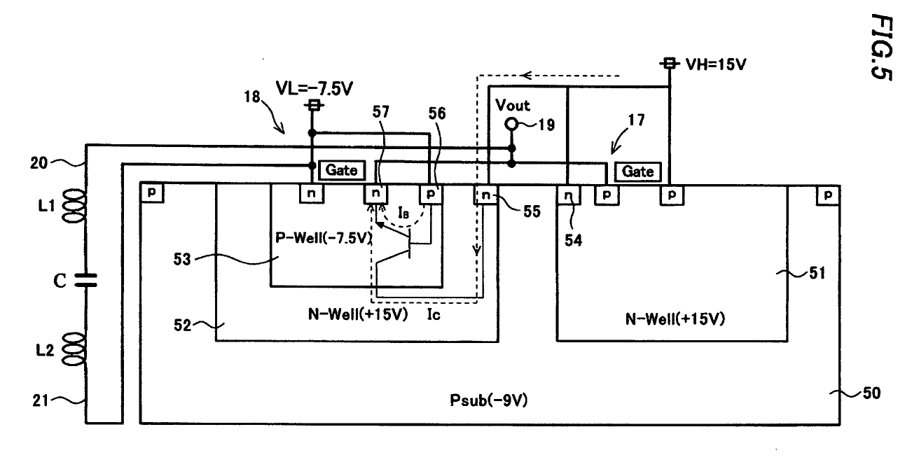

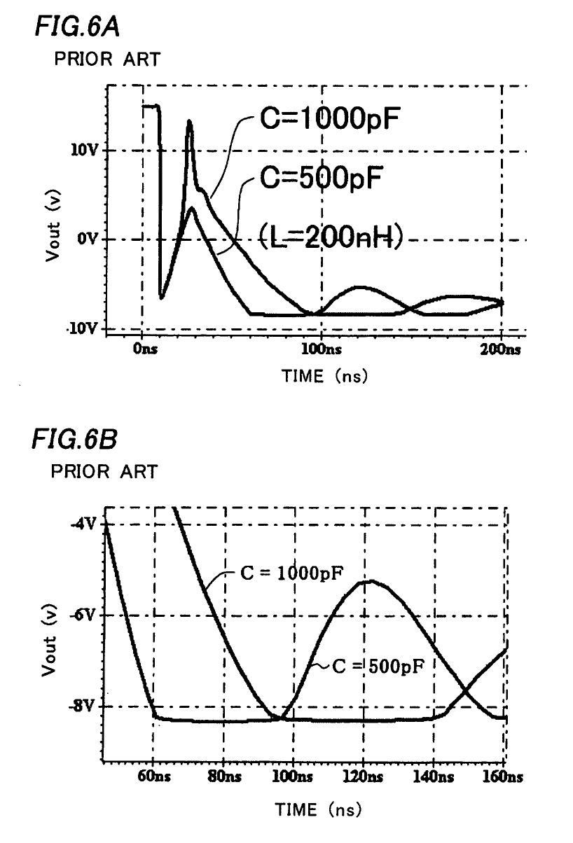

Next, a driver circuit according to an embodiment of this invention will be explained referring to the drawings. FIG. 1 is a circuit diagram of the driver circuit. The same components in FIG. 1 as in FIG. 3 (a circuit diagram according to a prior art) are given the same symbols, and the explanations thereof are omitted. And a structure of a P-channel type MOS transistor 17 and an N-channel type MOS transistor 18 which constitute an output inverter INV6 is same as the cross-sectional structure shown in FIG. 5.

The driver circuit of this embodiment differs from the driver circuit of the prior art in that an output of an inverter INV2 is applied to each of inputs of inverters INV4 and INV5 that control the output stage inverter INV6, that an output of the inverter INV4 is applied to a gate of an N-channel type MOS transistor 18 (an output transistor) of the output stage inverter INV6 and that an output of the inverter INV5 is applied to a gate of a P-channel type MOS transistor 17 (output transistor) of the output stage inverter INV6.

The inverter INV4 is made of a P-channel type MOS transistor 25, a first resistor R1 and an N-channel type MOS transistor 26 connected in the order described above between a positive high power supply electric potential VH (+15V, for example) and a negative high power supply electric potential VL (−7.5V, for example), making a connecting node between the first resistor R1 and the N-channel type MOS transistor 26 an output terminal of the inverter INV4. The first resistor R1 is inserted as a drain resistor of the P-channel type MOS transistor 25, and limits a current flowing through the P-channel type MOS transistor 25 when the P-channel type MOS transistor 25 is turned on.

Consequently, an electric potential at the gate of the N-channel type MOS transistor 18 (output transistor) of the output stage inverter INV6 rises slowly. Corresponding to it, the N-channel type MOS transistor 18 (output transistor) also turns on slowly. As a result, the ringing in the output voltage Vout of the output stage inverter INV6 is suppressed and the overshoot can be limited.

The first resistor R1 is preferably made of an ion-implanted resistor layer formed by injecting impurity ions into the semiconductor substrate 50. ON-resistance of the P-channel type MOS transistor 25 may be increased instead of inserting the first resistor R1. More specifically, it is preferable in order to limit the overshoot that a size ratio (a channel width W/a channel length L) of the P-channel type MOS transistor 25 is less than ⅕ of a size ratio of the N-channel type MOS transistor 26.

The overshoot of the output voltage Vout of the output stage inverter INV6 can be further limited by making the size ratio of the P-channel type MOS transistor 25 less than ⅕ of the size ratio of the N-channel type MOS transistor 26 in addition to inserting the first resistor R1.

FIG. 2 shows a result of simulation of the output voltage Vout of the output stage inverter INV6 when the output voltage Vout changes from the high level to the low level. A vertical axis represents Vout while a horizontal axis represents time. The result of the simulation shows clearly that the ringing and the overshoot in the output voltage Vout are reduced. And it is confirmed that the abnormal reduction in the positive high power supply electric potential VH observed in the driver circuit according to the prior art does not occur in an actual driver circuit according to the embodiment.

In the driver circuit described above, the first resistor R1 is inserted in order to limit the overshoot when the output voltage Vout of the output stage inverter INV6 changes from the high level to the low level. Similarly, a second resistor R2 may be inserted as shown in FIG. 1 in order to limit the overshoot when the output voltage Vout of the output stage inverter INV6 changes from the low level to the high level.

That is, the inverter INV5 is made of a P-channel type MOS transistor 27, the second resistor R2 and an N-channel type MOS transistor 28 connected in the order described above between the positive high power supply electric potential VH (+15V, for example) and the negative high power supply electric potential VL (−7.5V, for example), making a connecting node between the second resistor R2 and the P-channel type MOS transistor 27 an output terminal of the inverter INV5. The second resistor R2 is inserted as a drain resistor of the N-channel type MOS transistor 28, and limits a current flowing through the N-channel type MOS transistor 28 when the N-channel type MOS transistor 28 is turned on.

Consequently, an electric potential at the gate of the P-channel type MOS transistor 17 (output transistor) of the output stage inverter INV6 falls slowly. Corresponding to it, the P-channel type MOS transistor 17 (output transistor) turns on slowly. As a result, the overshoot of the output voltage Vout of the output stage inverter INV6 can be limited.

The second resistor R2 is preferably made of an ion-implanted resister layer formed by injecting impurity ions into the semiconductor substrate 50. ON-resistance of the N-channel type MOS transistor 28 may be increased instead of inserting the second resistor R2. More specifically, it is preferable in order to limit the overshoot that a size ratio (a channel width W/a channel length L) of the N-channel type MOS transistor 28 is less than ⅕ of a size ratio of the P-channel type MOS transistor 27.

The overshoot of the output voltage Vout of the output stage inverter INV6 can be further limited by making the size ratio of the N-channel type MOS transistor 28 less than ⅕ of the size ratio of the P-channel type MOS transistor 27 in addition to inserting the second resistor R2. It is preferable that resistance of each of the first and second resistors R1 and R2 is in a range between 20KΩ and 30KΩ approximately.

The abnormal reduction in the positive high power supply electric potential VH outputted by the positive booster charge pump circuit 12 at switching of the output stage inverter in the driver circuit can be prevented, since the overshoot of the output voltage of the output stage inverter is limited according to the driver circuit of this embodiment. As the ringing and the overshoot are large in the driver circuit of a high voltage output (about 15V and above, for example), this invention is particularly effective when applied to such a driver circuit.

What is claimed is:

1. A driver circuit comprising:
a first inverter comprising a first MOS transistor and a second MOS transistor connected in series between a first electric potential and a second electric potential;
a first power supply circuit that generates the first electric potential;
a second power supply circuit that generates the second electric potential;
a second inverter comprising a third MOS transistor and a fourth MOS transistor connected in series between the first electric potential and the second electric potential;
a third inverter comprising a fifth MOS transistor and a sixth MOS transistor connected in series between the first electric potential and the second electric potential; and
a first resistor inserted between the third MOS transistor and the fourth MOS transistor in order to limit an overshoot of an output of the first inverter,
wherein an output of the second inverter is applied to a gate of the first MOS transistor and an output of the third inverter is applied to a gate of the second MOS transistor.

2. The driver circuit of claim 1, further comprising a second resistor inserted between the fifth MOS transistor and the sixth MOS transistor in order to limit the overshoot of the output of the first inverter.

3. The driver circuit of claim 1, wherein the first resistor is made of an ion-implanted layer.

4. The driver circuit of claim 1, wherein the second MOS transistor is formed in a first well of a second conductivity type, the first well being formed in a surface of a semiconductor substrate of a first conductivity type, and the first MOS transistor is formed in a third well of the first conductivity type, the third well being formed in a second well of the second conductivity type and the second well being formed in the surface of the semiconductor substrate.

5. The driver circuit of claim 4, wherein the first well and the second well are set at the first electric potential and the third well is set at the second electric potential.

6. A driver circuit comprising:
a first inverter comprising a first MOS transistor and a second MOS transistor connected in series between a first electric potential and a second electric potential;
a first power supply circuit that generates the first electric potential;
a second power supply circuit that generates the second electric potential;
a second inverter comprising a third MOS transistor and a fourth MOS transistor connected in series between the first electric potential and the second electric potential; and
a third inverter comprising a fifth MOS transistor and a sixth MOS transistor connected in series between the first electric potential and the second electric potential,
wherein an output of the second inverter is applied to a gate of the first MOS transistor and an output of the third inverter is applied to a gate of the second MOS transistor, and a ratio of a channel width to a channel length of the third MOS transistor is equal to or less than one fifth of a ratio of a channel width to a channel length of the fourth MOS transistor.

7. The driver circuit of claim 6, further comprising a first resistor inserted between the third MOS transistor and the fourth MOS transistor in order to limit an overshoot of an output of the first inverter.

8. The driver circuit of claim 6, further comprising a second resistor inserted between the fifth MOS transistor and the sixth MOS transistor in order to limit an overshoot of an output of the first inverter.

9. The driver circuit of claim 6, wherein the second MOS transistor is formed in a first well of a second conductivity type, the first well being formed in a surface of a semiconductor substrate of a first conductivity type, and the first MOS transistor is formed in a third well of the first conductivity type, the third well being formed in a second well of the second conductivity type and the second well being formed in the surface of the semiconductor substrate.

10. The driver circuit of claim 9, wherein the first well and the second well are set at the first electric potential and the third well is set at the second electric potential.

11. A driver circuit comprising:
a first inverter comprising a first MOS transistor and a second MOS transistor connected in series between a first electric potential and a second electric potential;
a first power supply circuit that generates the first electric potential;
a second power supply circuit that generates the second electric potential;
a second inverter comprising a third MOS transistor and a fourth MOS transistor connected in series between the first electric potential and the second electric potential; and
a third inverter comprising a fifth MOS transistor and a sixth MOS transistor connected in series between the first electric potential and the second electric potential,
wherein an output of the second inverter is applied to a gate of the first MOS transistor and an output of the third inverter is applied to a gate of the second MOS transistor, and a ration of a channel width to a channel length of the sixth MOS transistor is equal to or less than one fifth of a ratio of a channel width to a channel length of the fifth MOS transistor.

12. The driver circuit of claim 11, wherein the second MOS transistor is formed in a first well of a second conductivity type, the first well being formed in a surface of a semiconductor substrate of a first conductivity type, and the first MOS transistor is formed in a third well of the first conductivity type, the third well being formed in a second well of the second conductivity type and the second well being formed in the surface of the semiconductor substrate.

13. The driver circuit of claim 12, wherein the first well and the second well are set at the first electric potential and the third well is set at the second electric potential.
